(19) United States
(12) Patent Application Publication
(10) Pub. No.: US 2012/0267050 A1
(43) Pub. Date: Oct. 25, 2012

(54) PLASMA PROCESSING APPARATUS

(75) Inventors: Yusaku SAKKA, Shunan (JP); Ryoji Nishio, Kudamatsu (JP); Tadayoshi Kawaguchi, Kudamatsu (JP)

(73) Assignee: Hitachi High-Technologies Corporation

(21) Appl. No.: 13/190,654

(22) Filed: Jul. 26, 2011

(30) Foreign Application Priority Data
Apr. 21, 2011 (JP) 2011-094601

(51) Int. Cl. H01L 21/3065

(52) U.S. Cl. 156/345.39

(57) ABSTRACT

A uniform plasma processing to a sample is performed by adjusting the distribution of the induced magnetic field in an inductively-coupled-plasma processing apparatus and correcting the plasma distribution on the sample. Between an induction coil and a dielectric window a conductor is provided along the induction coil and side by side with at least a part of the induction coil in its circumferential direction. The conductor is set up at a location where the intensity of the induced magnetic field generated from the induction coil is wished to be weakened and the relationship of Lp≧Lr is satisfied, letting the shortest distance from the induction coil to the surface of the conductor be Lr and letting the shortest distance from the induction coil to the plasma generated directly under the dielectric window be Lp.

### BACKGROUND OF THE INVENTION

The present invention relates to a plasma processing apparatus, more particularly to a plasma processing apparatus which is suitable for an apparatus using an inductively coupled plasma source.

In the field of semiconductor-device fabrication, an ICP (Inductively Coupled Plasma) processing apparatus is used for etching or surface processing of a sample. As a conventional ICP processing apparatus, as disclosed in JP-A-2007-158373, there has been known an ICP processing apparatus which includes a gas ring which constitutes part of a vacuum processing chamber and is equipped with an injection hole of a processing gas, a bell jar which forms the vacuum processing chamber by covering the upper portion of the gas ring, an antenna which is deployed on the upper portion of the bell-jar and supply a radio-frequency electric field in the vacuum processing chamber to generate plasma, a mounting stage for mounting a wafer inside the vacuum processing chamber, and a Faraday shield which is deployed between the antenna and the bell jar and to which a radio-frequency bias voltage is applied.

In an ICP processing apparatus like this, as disclosed in JP-A-2004-022988, a technology has been known which enhances the uniformity of the plasma against the plasma non-uniformity caused by the influence of an external magnetic field by enclosing the entire plasma processing chamber with a magnetic material to shield the external magnetic field.

### SUMMARY OF THE INVENTION

In general, in a plasma processing apparatus using the ICP source, it is known that non-uniformity of the current distribution of an induction coil is inevitable and that the plasma distribution becomes non-uniform along a circumferential direction of the induction coil. This fact gives rise to the occurrence of eccentricity of the plasma, which means that the centerline of the plasma that diffuses on a wafer deviates from the centerline of the induction coil. Also, in an electric-feeding portion of the induction coil, the plasma distribution along the circumferential direction of the induction coil becomes non-uniform. The eccentricity of the plasma on the wafer can also be caused by the exhaust eccentricity inside the plasma processing chamber.

The inventors have also experimentally confirmed that the eccentricity occurs in the distribution of the plasma that diffuses on the wafer. In the experiment, the eccentricity caused by a magnetic field was simulated and the plasma processing was performed with an about 0.4-mT magnet set up outside the plasma processing chamber. This experiment indicated as a result that due to the minute magnetic field of 0.4 mT possessed by the magnet makes the distribution of the plasma that diffuses on the wafer vary significantly. This indicates that there is a possibility that the plasma will undergo an influence even from a minute magnetic field of an extent of the terrestrial magnetism. Moreover, there is a possibility that basically the same phenomenon will occur even by magnetic fields of a vacuum pressure gage and a motor which are mounted on the apparatus. Regarding the above-described eccentricity of the plasma diffused on the wafer, it is conceived that when the plasma generated in proximity to the induction coil inside the plasma processing chamber diffuses downward in the plasma processing chamber, it diffuses in an oblique direction by the effect of the minute magnetic field and the plasma becomes eccentric on the wafer. When an etching is performed while the plasma remains eccentric on the wafer, characteristics such as uniformity of the etching processing and perpendicularity of the etching profile become worse. Thus, as the requirement for the high-accuracy and high-speed etching processing rises these days, in order to perform stable etching processing the influence of the minute magnetic field becomes less negligible.

Incidentally, in JP-A-2004-022988, a method for eliminating the influence of the magnetic field is disclosed. From the viewpoint of practicability, however, it cannot be said that sufficient consideration has been given thereto and there exist three problems. The first is a problem on the performance. The plasma processing chamber requires apertures such as transportation slot for a sample to be processed and exhaust outlet of a processing gas so that it is substantially impossible to shield the magnetic field. Also, by surrounding with the magnetic material an induced magnetic field generated by the induction coil creates an induction loss inside the magnetic material and the capability of generating plasma is lowered. The second is a problem on the implementation. It requires a significant change in the design for covering with the magnetic material. Moreover, occasions of handling heavy objects increase during assembly of the apparatus and the degree of danger at work increases. The third is a problem on the cost. The magnetic material for covering the entire plasma processing chamber becomes necessary and it causes a tremendous amount of cost. These three problems turn out to be extremely serious problems for apparatuses for mass production.

The present invention has been devised in view of these problems and its objective is to provide a plasma processing apparatus which adjusts the distribution of the induced magnetic field and corrects the plasma distribution on a sample, and thereby allowing implementation of the uniform plasma processing to the sample.

In order to solve the above-described problems, in the present invention, there is provided a plasma processing apparatus including a vacuum processing chamber in which a plasma processing is applied to a sample, a dielectric window which forms an upper surface of the vacuum processing chamber, a gas-introducing unit for introducing a gas into the vacuum processing chamber, a sample stage which is deployed in the vacuum processing chamber for mounting the sample thereon, an induction coil which is provided over the dielectric window, a radio-frequency power-supply for supplying a radio-frequency power to the induction coil, and a conductor which is set up between the induction coil and the dielectric window, is electrically connected in a full circle so that an induced current can be formed, is provided side by side with at least a part of the induction coil in its circumferential direction along the induction coil, and is set up at a location where the intensity of an induced magnetic field generated from the induction coil is wished to be weakened and the relationship of Lp≧Lr is satisfied letting the shortest distance from the induction coil to the surface of the conductor be Lr and letting the shortest distance from the induction coil to a plasma generated directly under the dielectric window be Lp.

According to the present invention, it becomes possible to adjust the distribution of the induced magnetic field generated by the induction coil, and thereby to correct the plasma distribution on a sample. Consequently, there exists an advantage of being capable of acquiring desired processing performances.

Other objects, features, and advantages of the invention will become apparent from the following description of the embodiments of the invention taken in conjunction with the accompanying drawings.

### BRIEF DESCRIPTION OF THE DRAWINGS

FIG. 1 is a longitudinal cross-sectional diagram for illustrating a plasma processing apparatus which is an embodiment according to the present invention;

FIG. 2 is a plan view of the apparatus obtained when FIG. 1 is viewed from A;

FIG. 3 is an arrow view diagram for illustrating the details of an induction coil obtained when FIG. 1 is viewed from B;

FIG. 4 is a longitudinal cross-sectional diagram for illustrating the details of the C portion in FIG. 1;

FIGS. 5A to 5C are diagrams of simulation results for illustrating the distributions of induced magnetic field depending on the position of the conductor ring;

FIG. 6 is a diagram for illustrating the diffusion of the plasma in a case where only the magnetic field generated by the induction coil is present;

FIG. 7 is a diagram for illustrating the diffusion of the plasma in a case where the magnetic field other than that generated by the induction coil is present;

FIG. 8 is a diagram for illustrating the diffusion of the plasma in a case where a conductor ring is applied to the apparatus illustrated in FIG. 7;

FIG. 9 is a diagram for illustrating the distribution of the etching rate in the sample plane;

FIGS. 10A and 10B are cross-sectional diagrams for illustrating other embodiments of the installation position of the conductor ring in the plasma processing apparatus according to the present invention;

FIGS. 11A to 11C are diagrams for illustrating other embodiments of the shape of the conductor ring in the plasma processing apparatus according to the present invention;

FIGS. 12A to 12E are diagrams for illustrating other embodiments of the shape of the Faraday shield in the plasma processing apparatus according to the present invention; and

FIG. 13 is a diagram for illustrating a combination example of the induction coil and the Faraday shield in the plasma processing apparatus according to the present invention.

### DETAILED DESCRIPTION OF THE EMBODIMENTS

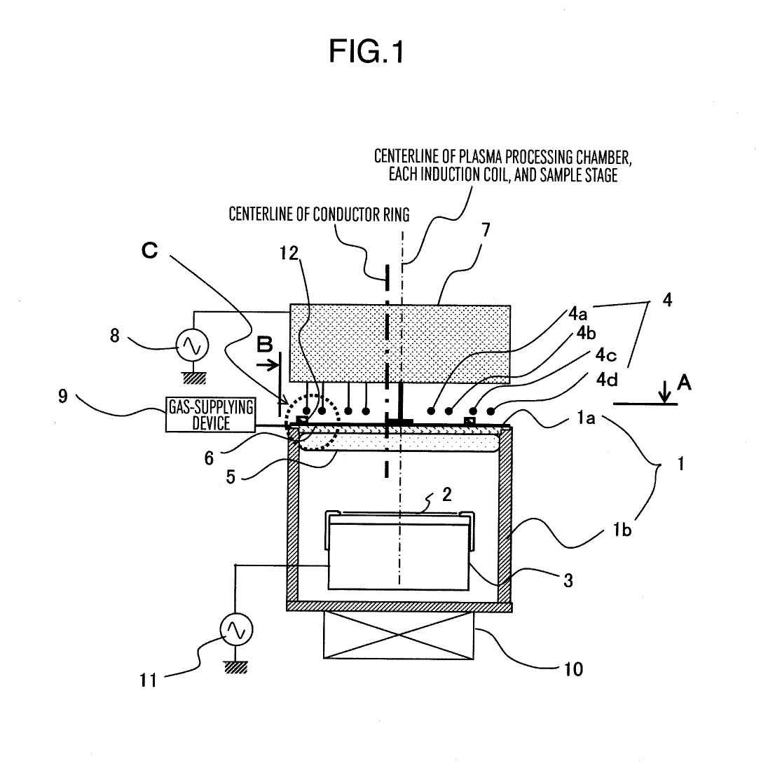

Hereinafter, referring to FIGS. 1 to 9, an explanation will be given below concerning an embodiment of a plasma processing apparatus according to the present invention.

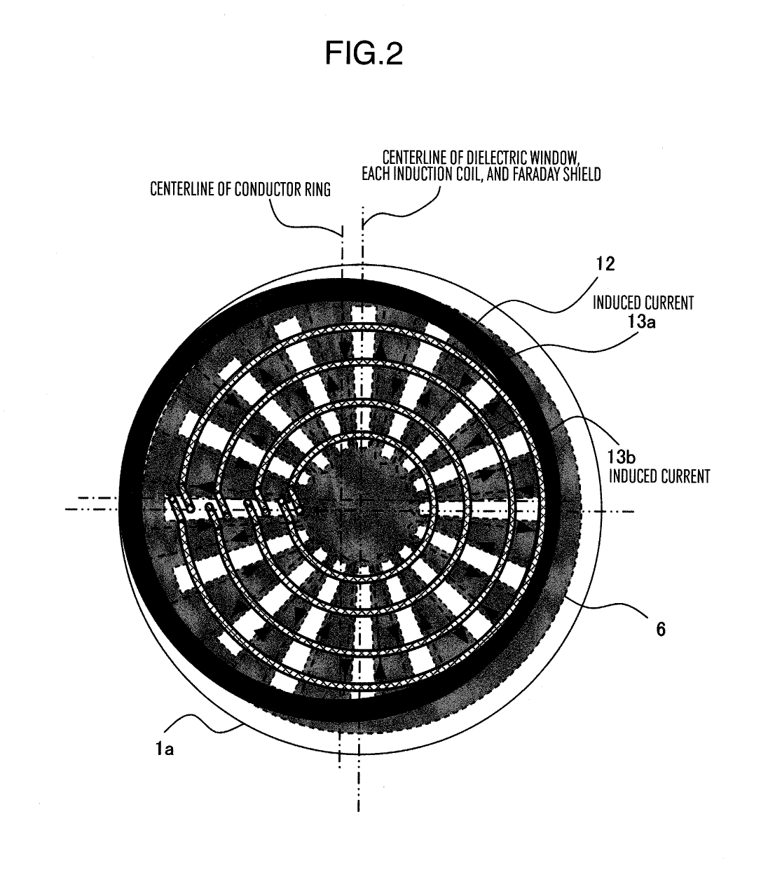

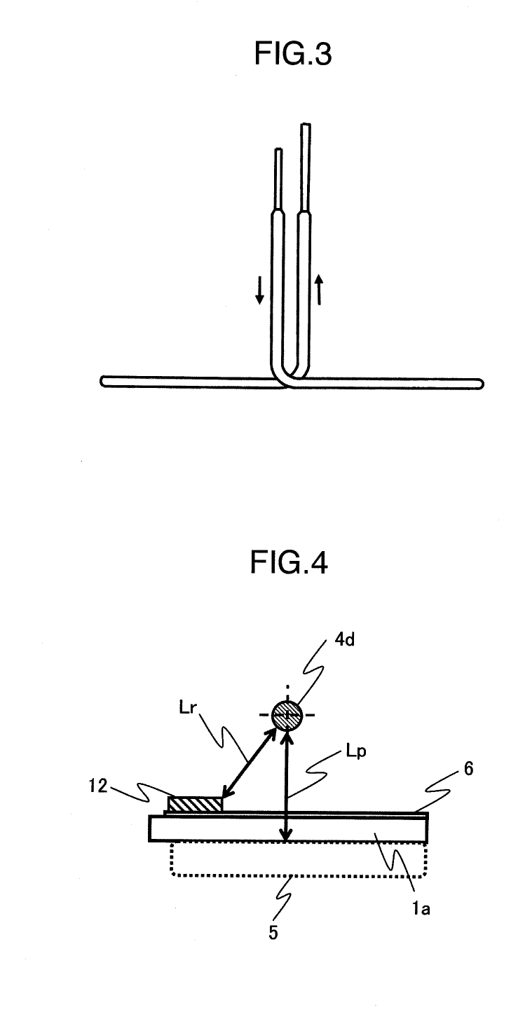

FIG. 1 illustrates a longitudinal cross-sectional diagram of an ICP processing apparatus. A dielectric window 1a, which is a top board capable of keeping the inside airtight, is installed on the upper aperture portion of a cylindrical processing vessel 1b. The dielectric window 1a is formed of an insulating material permeable by electromagnetic wave or, for example, electrically non-conductive material such as alumina (Al₂O₃) or ceramic. An induction antenna is deployed over the dielectric window 1a that becomes the outside upper surface of the vacuum processing chamber 1. In the current embodiment, as illustrated in FIG. 2, the induction antenna is constituted of induction coils 4a to 4d (or induction coils 4), which form single turns with different radii from each other and are deployed in a concentric manner. Each of the induction coils 4a to 4d has electric-feeding ends at both ends thereof (both ends become the electric-feeding ends since AC power is supplied) and is formed in such a shape that it is wound more than one full circle with one of the electric-feeding ends as a start point to partially overlap with itself and equipped with the other electric-feeding end at the other end. It is intended to prevent a discontinuous portion of a coil from being formed on the circumference so that the induced magnetic field becomes weak. As will be described in detail later, since a strong induced magnetic field is adjustable by providing an interference member thereto while a weak induced magnetic field cannot be made stronger, weakening of the induced magnetic field is avoided by providing the partially-overlapped portion. As illustrated in FIG. 3, induction coils 4 are coated with an insulating material including the rising edges of the electric-feeding ends to prevent contact at the partially-overlapped portion. Induction coils 4 are connected to a first radio-frequency power-supply 8 via a matching box 7. The first radio-frequency power-supply 8 generates radio-frequency power of, for example, 13.56-MHz or 27.12-MHz.

A Faraday shield 6 is deployed between the induction coils 4 and the dielectric window 1a. In the current embodiment, the Faraday shield 6 is installed on the upper surface of the dielectric window 1a. The Faraday shield 6, which is formed of a metallic conductor, is so fabricated as to be continuous in the circumferential direction in each of its central portion and its outer-circumferential portion and to be equipped with radial slits within an area between the central portion and the outer-circumferential portion. The dielectric window 1a, the Faraday shield 6, and the induction coils 4 are installed concentric and in parallel to each other with predetermined spacings between any two of them. Also, in the current embodiment, on the upper surface of the Faraday shield 6, which is the opposite side of the Faraday shield 6 to the side of the dielectric window 1a, a plate-shaped conductor ring 12 is installed off the center of the Faraday shield 6 and not concentric; that is, the conductor ring 12 is not concentric with respect to the center of the induction coils 4. The conductor ring 12 exhibits its advantageous effect when it is not concentric with the induction coils 4, which will be described later.

The conductor ring 12 is ring-shaped as illustrated in FIG. 2 and is formed of a conductor such as, for example, aluminum or stainless steel. Although in the current embodiment the conductor ring 12 is 10-mm wide and 5-mm thick, the advantages of the present invention are not limited to those at these dimensions. As illustrated in FIG. 4, the conductor ring 12 is provided in contact with the Faraday shield 6 so that it is in electrical connection with the Faraday shield 6 and arranged with a predetermined spacing (Lr) from the induction coil 4d.

A process-gas supply channel, whose illustration is omitted, is formed on the side of the dielectric window 1a toward the inside of the vacuum processing chamber 1 and is connected with a gas-supplying device 9. In the vacuum processing chamber 1a sample stage 3 is installed while being supported on the processing vessel 1b by a supporting member whose illustration is omitted. On the top surface of the sample stage 3 a sample-mount surface is formed so that a sample 2 is deployed by a transportation device, whose illustration is omitted, and can be held thereon using an electrostatic chuck or the like. A second radio-frequency power-supply 11 is connected to the sample 2 deployed on the top surface of the sample stage 3 so that a bias voltage can be applied during processing of the sample. The second radio-frequency power-supply 11 generates a radio-frequency power of, for example, 800-KHz or 4-MHz, whose frequency is lower than the frequency of the first radio-frequency power-supply 8. On the lower surface of the processing vessel 1b an exhaust device 10 to decompress and evacuate inside the vacuum processing chamber 1 is installed.

In the plasma processing apparatus constituted as described above, first, the inside of the vacuum processing chamber 1 is decompressed and evacuated with the exhaust device 10 and a process gas, whose flow rate is controlled by the gas-supplying device 9, is supplied into the vacuum processing chamber 1 via the dielectric window 1a to set the inside of the vacuum processing chamber 1 at a predetermined pressure. Next, the first radio-frequency power-supply 8 supplies the radio-frequency power to the induction coils 4a to 4d via the matching box 7.

From this, a plasma 5 of the process gas is generated in the vacuum processing chamber 1. Based on the plasma distribution in the vacuum processing chamber 1, the powers to be supplied to the respective induction coils 4a to 4d can be adjusted by a control device, whose illustration is omitted.

The induced magnetic field radiated from the induction coils 4 undergoes the effects by the conductor ring 12 and the Faraday shield 6, passes through the dielectric window 1a, and propagates into the vacuum processing chamber 1. It has been known that the Faraday shield cuts off the capacitive component of the induction coils 4. Further, by configuring the Faraday shield 6 in contact with the conductor ring 12 electrically, adjustment of the density distribution of the plasma generation becomes possible.

Namely, since the conductor ring 12, which is a ring-shaped electrical conductor, exists between the induction coils 4 and the Faraday shield 6, an induced current 13a flows on the circumference of the conductor ring 12 as illustrated in FIG. 2 along the conductor ring 12 in the direction so that the induced current 13a cancels out the induced magnetic field generated by the induction coils 4. Furthermore, an induced current 13b, which is similar to the induced current 13a, also flows around each slit of the Faraday shield 6 because the conductor ring 12 is in electrical connection with the Faraday shield 6. Therefore, by deploying the conductor ring 12 such that the induced currents 13a and 13b flow at positions where the intensity of the induced magnetic field radiated from the induction coils 4 is wished to be weakened, the density distribution of the plasma generation can be adjusted.

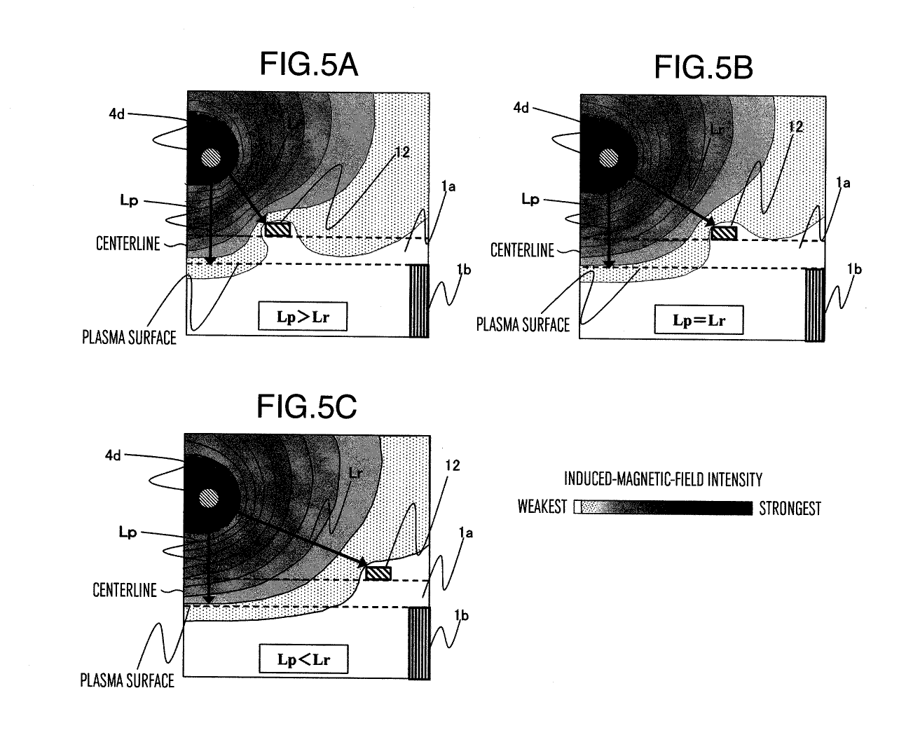

Here, referring to FIGS. 4 and 5A to 5C, the explanation will be given below concerning the effect of the conductor ring 12. As described earlier, the conductor ring 12 is set up above the Faraday shield 6; the conductor ring 12 is set up at a position so that the relationship of Lp≧Lr is satisfied at a location where the intensity of the induced magnetic field by the induction coils 4 is wished to be weakened while the shortest distance from the induction coil 4d to the surface of the conductor ring 12 is Lr and the shortest distance from the induction coil 4d to the plasma 5 to be generated directly under the dielectric window 1a is Lp. By making the position of the conductor ring 12 at the position where Lp≧Lr is satisfied with respect to the induction coil 4d, the mutual inductance between the induction coil 4d and the plasma 5 can be changed locally.

Hereinafter, an explanation will be given below concerning the relationship between the distances Lp and Lr with the position of the conductor ring 12 and the intensity distribution of the induced magnetic field using simulation results. FIGS. 5A to 5C are the contour diagrams for illustrating the intensity distribution of the induced magnetic field which are generated from the induction coil 4d when a 10-A/m current is constantly flown along the induction coil 4d. FIGS. 5A to 5C indicate that a lighter-color portion corresponds to the lower intensity of the induced magnetic field (the portion where the intensity of the induced magnetic field is the lowest is represented by the white-hollow display). Conversely, it is indicated that a darker-color portion corresponds to the higher intensity of the induced magnetic field. Usually, the induced magnetic field generated from the induction coil 4d extends from the induction coil 4d in a concentric manner to pass through the dielectric window 1a and to reach the inside of the vacuum processing chamber 1. The result becomes a distribution which is substantially the same contour lines of the intensity of the induced magnetic field illustrated in FIG. 5C.

FIG. 5A shows the simulation result for the case where the conductor ring 12 is set at the position where Lp>Lr is satisfied. At the position where the conductor ring 12 is set, the induced magnetic field generated from the induction coil 4d is shielded by the conductor ring 12 so that the induced magnetic field only on the inner side of the conductor ring 12, that is, on the side where the induction coil 4d exists, reaches the side of the dielectric window 1a. This is because, as described earlier, the induced magnetic field in the area in proximity to the conductor ring 12 is weakened by the effect of the induced currents generated along the conductor ring 12 since the conductor ring 12 is deployed at the closer distance Lr to the induction coil 4d than the distance Lp from the induction coil 4d to the plasma-generation surface. It should be noted that the induced magnetic field is supposed to be used for the plasma generation.

FIG. 5B shows the simulation result for the case where the conductor ring 12 is set at the position where Lp=Lr is satisfied. Also, FIG. 5C shows the simulation result for the case where the conductor ring 12 is set at the position where Lp<Lr is satisfied. In FIGS. 5B and 5C as well, as is the case with FIG. 5A, the induced currents for shielding the induced magnetic field from the induction coil 4d are generated at the positions where the conductor ring 12 is placed. It is shown, however, that the further the conductor ring 12 is located away from the induction coil 4d, the more widely the areas of the induced magnetic field expand which reaches the inside of the vacuum processing chamber 1 as seen in FIGS. 5B and 5C.

From this fact, it is understood that the density distribution of the plasma generation formed in the vacuum processing chamber 1 changes depending on the installment position of the conductor ring 12. In other words, by adjusting the position of the conductor ring 12 the density distribution of the plasma generation can be adjusted. Incidentally, the case where the position of the conductor ring 12 is in the relation of Lp<Lr does not exist practically when the outermost-side induction coil 4d of the induction coils 4 exists almost up to the outer edge of the processing chamber like the present embodiment (that is, when the value of [inner diameter of the processing chamber (diameter D)—diameter of the induction coil assembly (diameter d)] falls within about 2 Lp). Even then, by placing the conductor ring 12 at the position where Lp≧Lr is satisfied, it becomes possible to adjust the density distribution of the plasma generation directly under the dielectric window 1a.

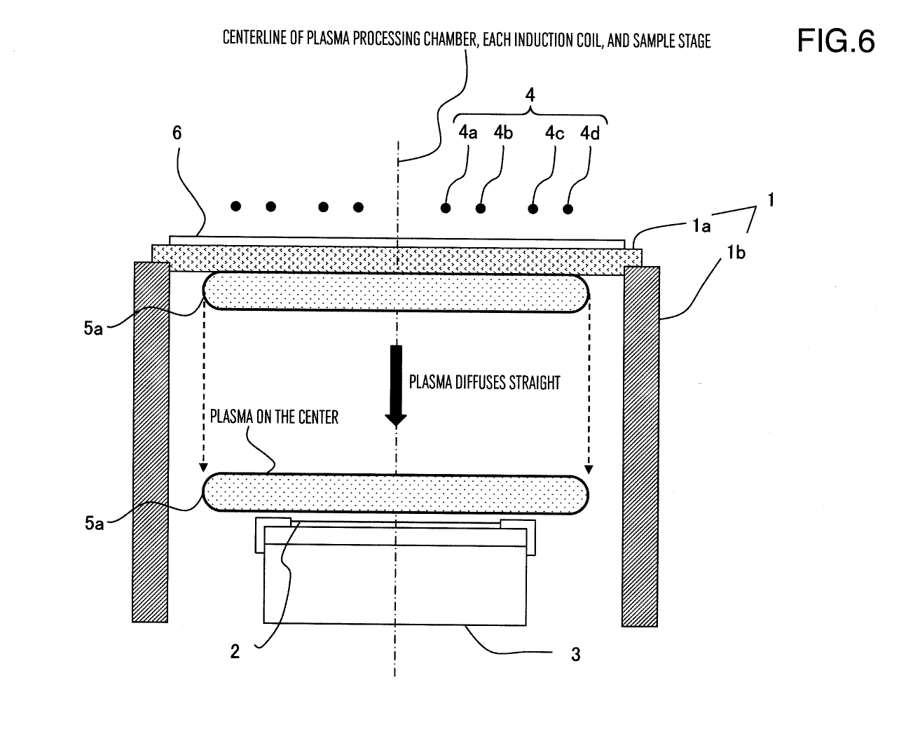

Next, referring to FIGS. 6 to 8, an explanation will be given below concerning the correction of the position eccentricity of the plasma according to the present embodiment, where the above-described effect of the conductor ring 12 is taken advantage of.

FIG. 6 illustrates the diffusion of the plasma in a case where the influence exerted by another magnetic field other than the induced magnetic field generated from the induction coils 4 is absent. In this case, the plasma 5a, which is generated directly under the dielectric window 1a, diffuses straightforward onto the sample 2 by the flow by the concentric exhaust device 10 existing under the sample stage 3 and no eccentricity of the plasma would be observed.

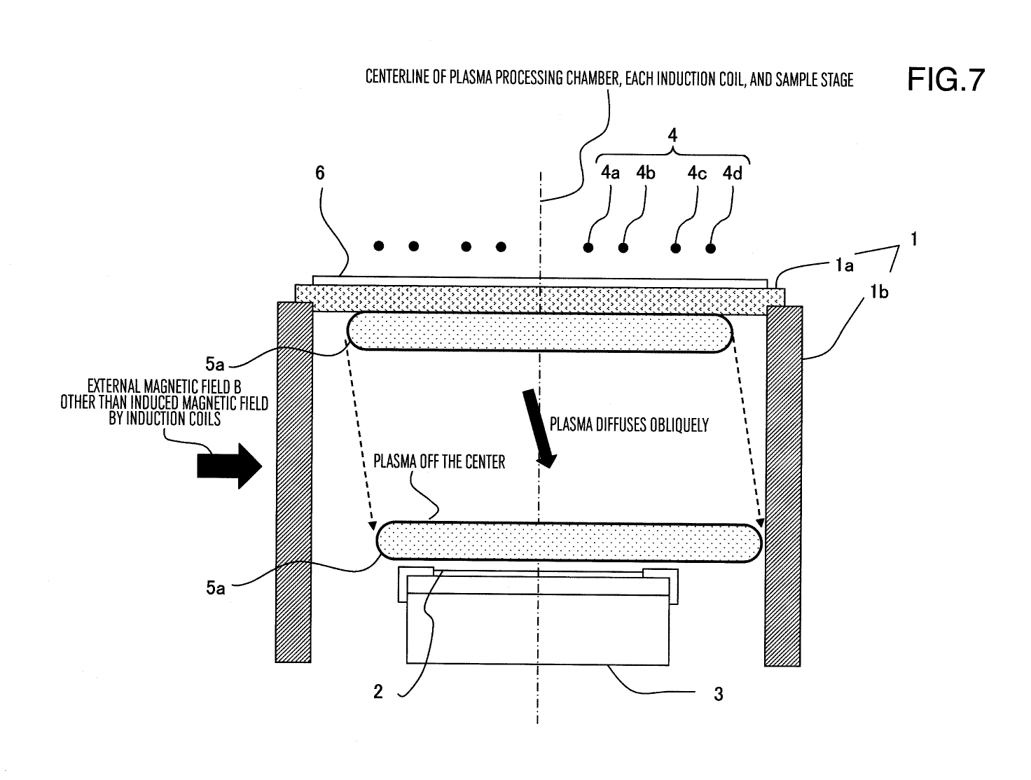

In contrast thereto, in a case where, as illustrated in FIG. 7, an external magnetic field (here, horizontal magnetic field B (which, hereinafter, will be referred to as “external DC magnetic field”) in the direction of left-to-right on the plane of the paper) is present other than the induced magnetic field generated from the induction coils 4, the diffusion undergoes the influence from this external DC magnetic field.

FIG. 7 illustrates the diffusion of the plasma in this case. The charged particles in the area where the horizontal magnetic field B in the plasma processing chamber is applied thereto perform spiral motions with respective to the horizontal magnetic field B by the Lorentz force. Accordingly, the plasma 5a generated directly under the dielectric window 1a diffuses in an oblique direction (the lower-right direction on the drawing) by the effect of the horizontal magnetic field B. Therefore, the plasma 5a that diffuses on the sample 2 becomes off the center of the sample 2.

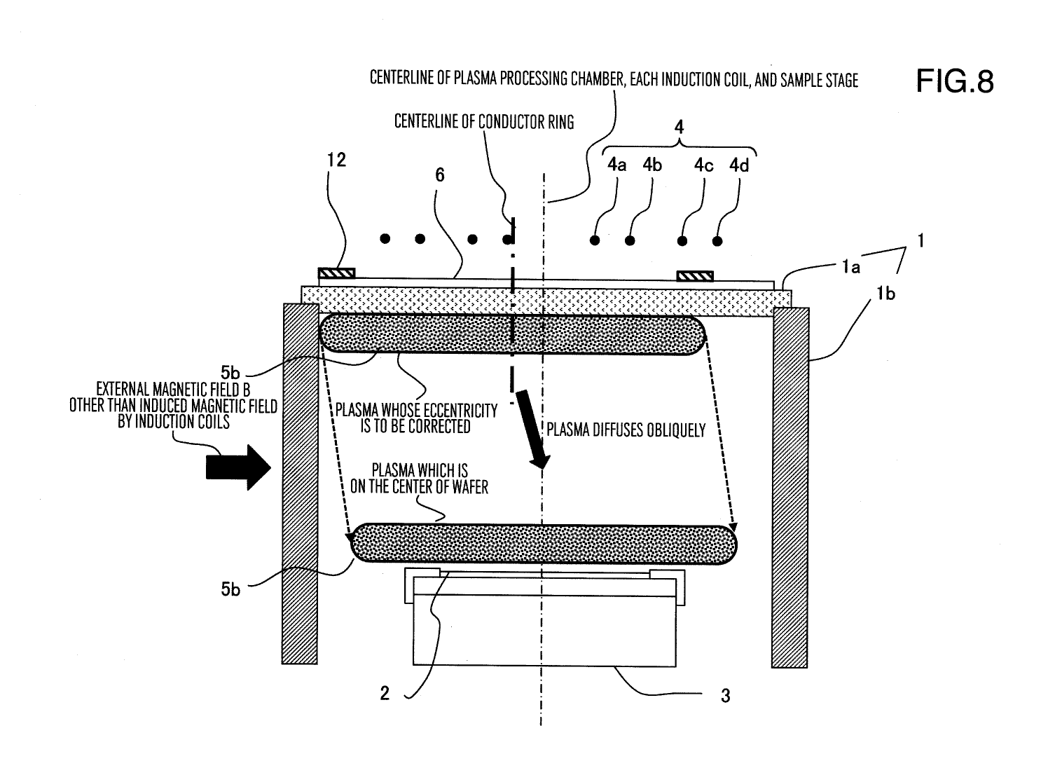

FIG. 8 illustrates the diffusion of the plasma in the state illustrated in FIG. 7, where the external DC magnetic field other than the induced magnetic field from the induction coils 4 is applied thereto, and in the case where the conductor ring 12 in the present embodiment is set up. In the case illustrated in FIG. 7 where the conductor ring 12 is not present, the plasma 5a that diffuses on the sample 2 is off toward the right side of the drawing by the effect of the horizontal magnetic field B. In contrast thereto, by placing the conductor ring 12 with a shift to the left with reference to the centerline of the plasma processing chamber on the drawing as illustrated in FIG. 8, the induced magnetic field generated from the induction coils 4 on the right side of the drawing, that is, the induced magnetic field from the induction coils 4 in an area closer to the conductor ring 12, is weakened by the effect of the circular current (the induced current 13a) generated along the conductor ring 12 on the induced magnetic field by the induction coils 4. Then, only a low-density plasma is generated on the right side of the drawing directly under the dielectric window 1a and a high-density plasma which is off to the left of the drawing with reference to the center of the dielectric window 1a is generated substantially. In the case where the influence of the horizontal magnetic field B is present, the plasma directly under the dielectric window 1a, of which the density is low on the right side of the drawing, diffuses down toward the sample 2 while gradually displacing the area of its low-density plasma in the right of the drawing. Then, the eccentricity of the high-density plasma can be cancelled out on the sample 2 even when the horizontal magnetic field B has its effect.

In this way, by providing a unit for permitting an induced current to flow against the induced magnetic field from the induction coils 4 (an attenuation unit of the induced magnetic field) the intensity of the induced magnetic field from the induction coils 4 can be attenuated and the distribution of the induced magnetic field which passes through the dielectric window 1a can be adjusted. The set-up of the attenuation unit of the induced magnetic field is not limited to the upper portion of the dielectric window 1a and may also be formed in the dielectric window 1a or may also be provided on the lower surface thereof. Namely, it may be deployed between the induction coils 4 and the plasma-generation surface.

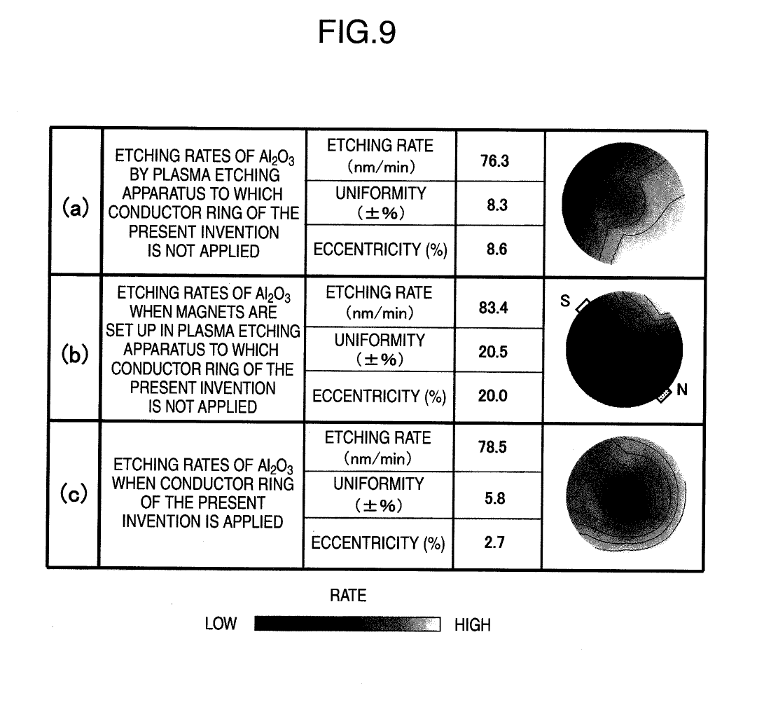

Referring to FIG. 9, the explanation will be given below concerning results of confirming the above-described effect in FIGS. 6 to 8 with the etching rates. The etching rates were measured in etching of thin-film samples composed of alumina (Al₂O₃) with a chlorine-based gas (a mixed gas of O₂ gas and BCl₃ gas) using an inductively-coupled-plasma etching apparatus for 200-mm-diameter substrates in which the eccentricity of the plasma was observed. FIG. 9 illustrates the in-sample-plane distributions of the etching rates at that time. Incidentally, the in-sample-plane distributions of the etching rates were obtained by measuring film thicknesses at specified points on the sample using a film-thickness measuring device before and after the etching processing and illustrated with contour lines. The contour lines indicate that a lighter-color portion corresponds to the higher etching rate and that, conversely, a darker-color portion corresponds to the lower etching rate. The effects according to the present embodiment have been confirmed by calculating the average value of the etching rates at the respective points in the sample plane, the in-sample-plane uniformity of the etching rates, and the eccentricity. Incidentally, the eccentricity is an indicator for indicating the degree of the eccentricity of the plasma that diffuses on the sample 2; the smaller the value of the eccentricity is, the less eccentric the plasma is.

First, in the plasma processing apparatus to which the conductor ring 12 is not applied or the forced external DC magnetic field is not provided, as illustrated in Row (a), the etching rates at the lower right of the drawing are higher in the in-sample-plane distribution of the etching rates. It is conceivable that the reason for this result is that the plasma has been off to the lower right by the influence of some DC magnetic field (for example, geomagnetism) other than the induced magnetic field by the induction coils. Next, Row (b) illustrates the in-sample-plane distribution of the etching rates in a case where the conductor ring 12 is not applied and magnets are set up on the periphery of the plasma processing apparatus. As a result of performing etching rate measurements with an S-pole and an N-pole of magnets (0.4 mT) being set up at the upper left and the lower right of the drawing, respectively, the location of high etching rates displaces to the upper right. This is because the DC magnetic field was added into the plasma by setting up the magnets compulsively. Also, as described above, even if the DC magnetic field other than the induced magnetic field by the induction coils is generated at any location, the eccentric position of the plasma that diffuses on the sample 2 can be estimated from the result of the in-sample-plane distribution of the etching rates.

From this result, the eccentricity of the plasma that diffuses on the sample 2 can be improved by setting up the conductor ring 12 based on the above-described estimation result of the eccentric position in Row (a). Next, Row (c) illustrates the result of the in-sample-plane distribution of the etching rates in a case where the conductor ring 12 in the present embodiment is applied. This result indicates that the in-sample-plane distribution of the etching rates becomes substantially uniform over the entire surface of the sample 2 and that the eccentricity is improved from 8.6% in Row (a) to 2.7%. In accompaniment with this improvement, the in-sample-plane uniformity of the etching rates can also be improved from 8.3% in Row (a) to 5.8%.

As explained so far, according to the present embodiment, there are advantages of adjusting the distribution of the induced magnetic field directly under the dielectric window 1a, correcting the eccentricity of the plasma that diffuses on the top surface of the sample 2, and acquiring the desire etching performances by setting up the conductor ring 12 with a shift with reference to the induction coils 4 to the predetermined position which is at the distance shorter than the distance from the induction coils 4 to the plasma-generation surface. Namely, the plasma processing apparatus of the present embodiment is capable of generating the plasma 5b for correcting the eccentricity of the plasma that diffuses on the sample 2 so that the eccentricity of the plasma that diffuses on the sample 2 can be improved. Incidentally, the plasma 5b for correcting the eccentricity of the plasma that diffuses on the sample 2 refers to the plasma which is capable of correcting the amount of the above-described eccentricity in advance so that the plasma on the sample 2 is not off the center when it diffuses in the oblique direction.

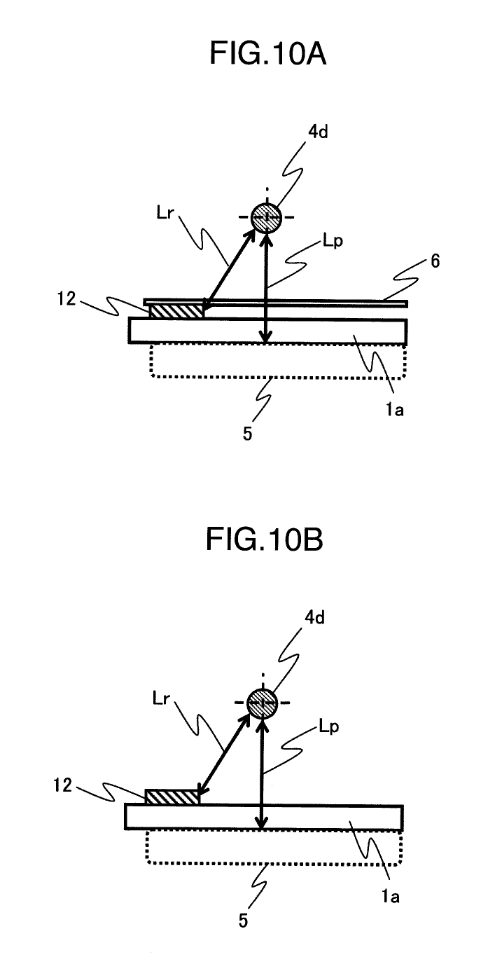

Incidentally, in the above-described embodiment, the conductor ring 12 is deployed between the induction coils 4 and the Faraday shield 6 and on the Faraday shield 6. The conductor ring 12, however, is not necessarily set up between the induction coils 4 and the Faraday shield 6; as illustrated in FIG. 10A, the conductor ring 12 may be set up between the Faraday shield 6 and the dielectric window 1a. Also, even though the conductor ring 12 is brought into the electrical connection with the Faraday shield 6 in the present embodiment, it may be brought into the electrical connection with a component which is capable of forming a closed circuit for the induced current to flow therealong since a current usually flows along a closed circuit. Therefore, it may be brought into the electrical connection with components such as, for example, the processing vessel 1b or the cover of the matching box 7. Also, when the closed circuit can be formed only by the conductor ring 12, the electrical connection with the above-described components is not necessary.

Moreover, when the effect of the Faraday shield 6 is unnecessary, the Faraday shield 6 may be removed as illustrated in FIG. 10B and the conductor ring 12 may merely be set up on the upper side of the dielectric window 1a. Namely, as long as the conductor ring 12 is set up between the induction coils 4 and the dielectric window 1a, the distribution of the induced magnetic field generated from the induction coils 4 can be corrected. Here, as long as the conductor ring 12 can form the closed circuit for the induced current to flow therealong, it is not necessary to be connected to the grounded main body of the apparatus such as, for example, the processing vessel 1b. Namely, the conductor ring 12 may be electrically floating.

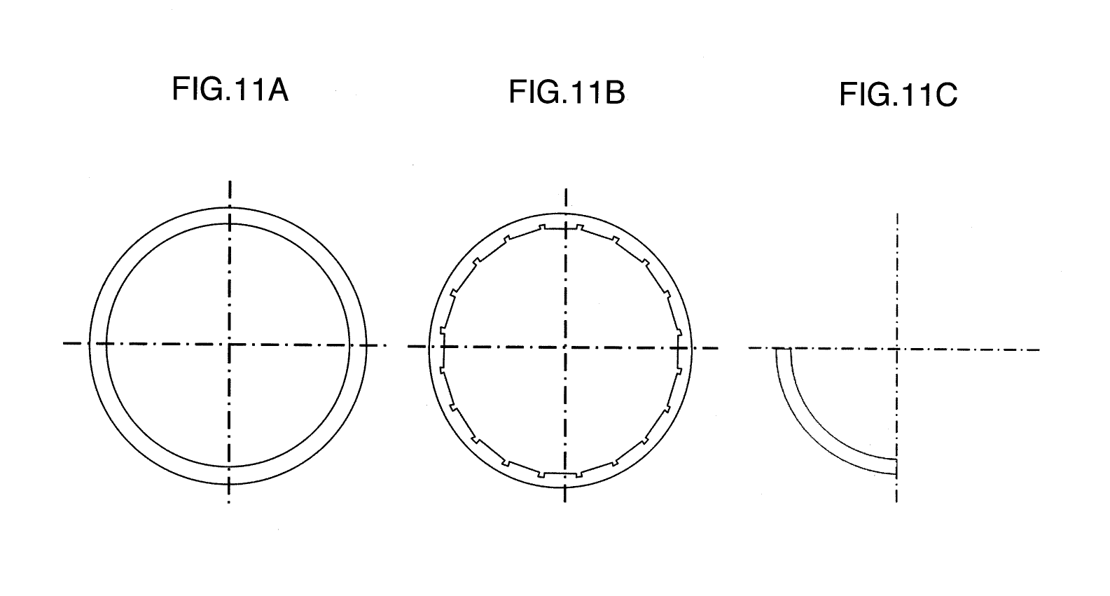

Also, the shape of the conductor ring 12 is not limited to the one illustrated in FIG. 2 (or FIG. 11A). For example, it may be a conductor ring of a comb-teeth shape, an elliptical conductor ring, or a conductor ring with varying widths along its circumference. Namely, it may be modified into a shape to obtain a desired distribution of the induced magnetic field. Also, since the conductor ring 12 in the present embodiment is brought into the electrical connection with the Faraday shield 6, it is not necessarily in the shape of a ring. Namely, the feature of the present invention is to locally correct the distribution of the induced magnetic field generated from the induction coils 4 by circular currents generated locally. Therefore, as long as being brought into the electrical contact with the Faraday shield 6, it may be an arc-shaped conductor plate as is illustrated in FIG. 11C, which is obtained by dividing the ring-shaped conductor ring 12 into its one-fourth, for example.

Also, a plurality of, or plural types of conductor rings 12 may be used simultaneously. Also, when a plurality of the conductor rings are used, they can be deployed independently of each other so that any eccentric position of the plasma distribution can be dealt with. Thus, it becomes easier to set up only the conductor rings, thereby allowing implementation of the adjustment in accordance with the machine differences among the plasma processing apparatuses.

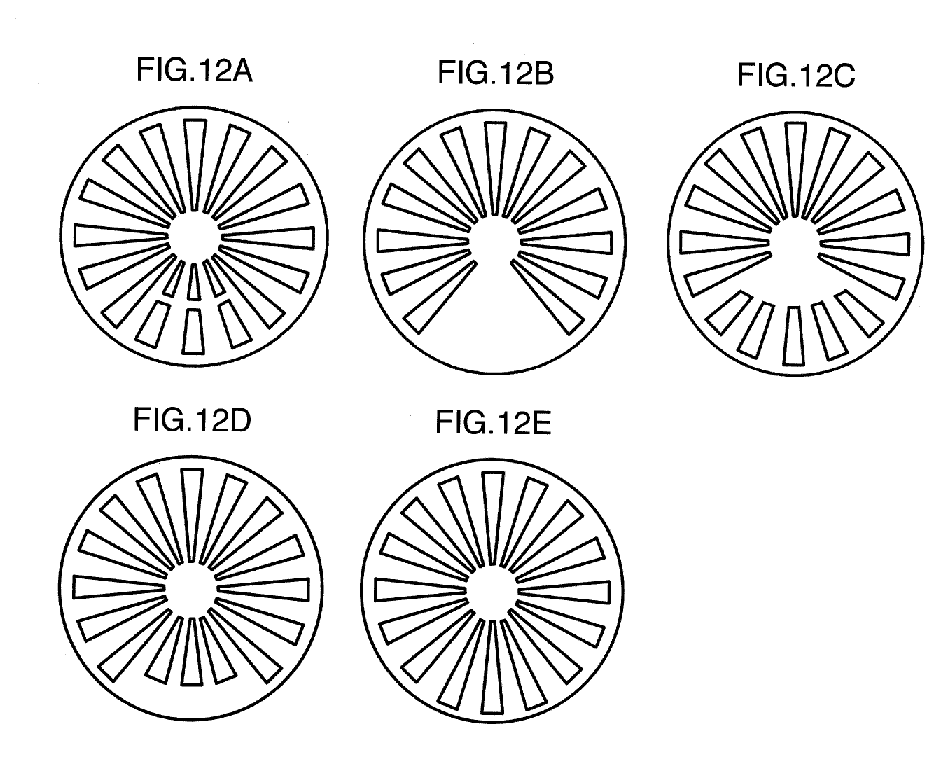

Further, even though the Faraday shield 6 and the conductor ring 12 are provided separately in the present embodiment, they may be provided as a single component which integrates the functions of the Faraday shield and the conductor ring. For example, the Faraday shield with the radial slits as illustrated in FIG. 12E may be modified by forming modified slits varying in lengths in the radius direction as illustrated in FIGS. 12A to 12D so that the shape of the conductor portion is changed.

FIG. 12A illustrates a Faraday shield in which at least one slit is divided in the radius direction thereby to form a conductor of the intermediate area therebetween. FIG. 12B illustrates a Faraday shield of the shape in which at least one slit is not provided in an arbitrary area. FIG. 12C illustrates a Faraday shield in which the length of at least one slit in the radius direction is changed thereby to shorten its central side so that the area of the conductor on the center part is enlarged. FIG. 12D illustrates a Faraday shield contrast to FIG. 12C in which the area of the conductor on the outer side is enlarged. By appropriately selecting depending on the distribution of the induced magnetic field and using these Faraday shields with various lengths of the slits in the radius direction or, in other words, the Faraday shields with arbitrary areas of slits being filled, they become equivalent to the ones for which a conductor plate is deployed in the direction intersecting with the plurality of slits so that the distribution of the induced magnetic field can be corrected.

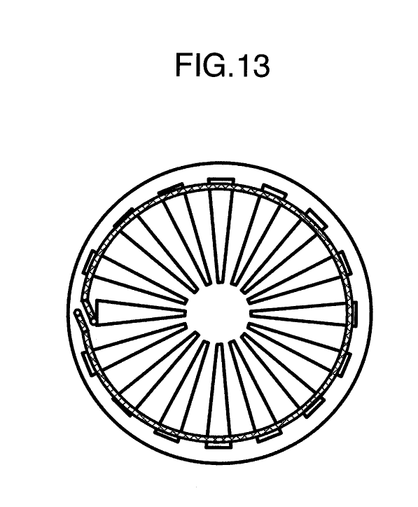

Referring to FIG. 13, an explanation will be given below concerning an installment example of the integrated-type Faraday shield which allows implementation of the correction of the distribution of the induced magnetic field at the electric-feeding ends of the induction coils 4 in the present embodiment. The parts of the electric-feeding ends of the induction coils 4 are partially overlapped with each other in the present embodiment and they become spots of the highest intensities of the induced magnetic field in the circumferential direction. Here, although a weak induced magnetic field cannot be made stronger, a strong induced magnetic field can be weakened by forming the local circular current described in the present embodiment. As illustrated in FIG. 13, by filling the slit which is at the location opposed to the electric-feeding ends of an induction coil, a strong magnetic field at the electric-feeding ends can be shielded so that the non-uniformity of the plasma in the circumferential direction of the induction coil can be improved. Incidentally, although single-turn induction coils are used in the present embodiment, an induction coil of plural-turn winding may also be used.

As explained so far, according to the present embodiment, it becomes possible to correct the distribution of the induced magnetic field generated from the induction coils 4 so that the non-uniformities of the plasma that diffuses on the top surface of the sample such as the eccentricity of the plasma that diffuses on the sample due to the influence of the DC magnetic field other than the induced magnetic field by the induction coils or the exhaust eccentricity in the plasma processing chamber, or non-uniformity of the plasma in the circumferential direction of the induction coils caused by the electric-feeding ends of the induction coils can be improved.

It should be further understood by those skilled in the art that although the foregoing description has been made on embodiments of the invention, the invention is not limited thereto and various changes and modifications may be made without departing from the spirit of the invention and the scope of the appended claims.

1. A plasma processing apparatus, comprising:
a vacuum processing chamber in which a plasma processing is applied to a sample;
a dielectric window which forms an upper surface of said vacuum processing chamber;
a gas-introducing unit for introducing a gas into said vacuum processing chamber;
a sample stage which is deployed in said vacuum processing chamber for mounting said sample thereon;
an induction coil which is provided over said dielectric window;
a radio-frequency power-supply for supplying a radio-frequency power to said induction coil; and
a conductor which is set up between said induction coil and said dielectric window, is electrically connected in a full circle so that an induced current can be formed, is provided side by side with at least a part of said induction coil in its circumferential direction along said induction coil, and is set up at a location where intensity of an induced magnetic field generated from said induction coil is wished to be weakened and relationship of Lp≧Lr is satisfied letting the shortest distance from said induction coil to surface of said conductor be Lr and letting the shortest distance from said induction coil to a plasma generated directly under said dielectric window be Lp.

2. The plasma processing apparatus according to claim 1, wherein
said conductor is of a ring shaped conductor.

3. The plasma processing apparatus according to claim 2, wherein
said ring-shaped conductor is provided off a center of said induction coil.

4. The plasma processing apparatus according to claim 1, further comprising a Faraday shield to which said conductor is electrically connected.

5. The plasma processing apparatus according to claim 1, further comprising a Faraday shield which includes a plurality of radial slits; and
wherein said conductor is formed by modifying shape of one of slits of said Faraday shield.

6. The plasma processing apparatus according to claim 1, wherein
said induction coil is a circular coil which is wound in a single turn and whose electric-feeding ends are partially overlapped with each other, and
said conductor is positioned under said electric-feeding ends of said induction coil.

7. A plasma processing apparatus, comprising:
a vacuum vessel comprising a top board which is formed of an insulating material which can pass through electromagnetic waves;
an induction antenna deployed opposing to said top board, an induced magnetic field from which is used to generate a plasma in said vacuum vessel; and
induced-magnetic-field attenuation means for partially cancelling out said induced magnetic field, deployed at an arbitrary position within said top board's pass-through surface and between said induction antenna and surface of said plasma directly under said top board.
